(19) United States
(12) Patent Application Publication
(10) Pub. No.: US 2006/0115774 A1
(43) Pub. Date: Jun. 1, 2006

(54) Method for reducing wafer charging during drying

(75) Inventors: Yu-Hsi Wang, Hsinchu City (TW); Shi-Che Wang, Hsinchu City (TW); Hua-Tal Lin, Yuang-Kang City (TW); Shang Ho Lin, Panchiao (TW); Ching-Yu Chang, Hsin-Chu (TW); Chin-Hsiang Lin, Hsin-chu (TW)

Correspondence Address: TUNG & ASSOCIATES, Suite 120, 838 West Long Lake Rd., Bloomfield Hills, MI, 48302, US

(73) Assignee: Taiwan Semiconductor Manufacturing Co., Ltd.

(21) Appl. No.: 10/999,625

(22) Filed: Nov. 30, 2004

(51) Int. Cl. G03F 7/00

(52) U.S. Cl. 430/331; 430/322

(57) ABSTRACT

A novel method for eliminating or reducing the accumulation of electrostatic charges on semiconductor wafers during spin-rinse-drying of the wafers is disclosed. The method includes rinsing a wafer; applying an ionic solution to the wafer; and spin-drying the wafer. During the spin-drying step, the ionic solution neutralizes electrostatic charges on the wafer as the wafer is rotated. This reduces the formation of defects in devices fabricated on the wafer, as well as prevents or reduces electrostatic interference with processing equipment during photolithographic and other fabrication processes.

### FIELD OF THE INVENTION

The present invention relates to photolithography techniques used in the fabrication of integrated circuits on semiconductor wafer substrates. More particularly, the present invention relates to a novel method for reducing electrostatic charging of wafers during photolithography, particularly during spin rinse drying of wafers after photolithography development, by applying an ionic solution to the wafers prior to the spin rinse drying step.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

The photolithography step of semiconductor production is a complex process which can generally be divided into an eight-step procedure including vapor prime, in which the surface of the wafer substrate is cleaned, dehydrated and primed to promote adhesion between the photoresist material and the substrate surface; spin coating, in which a quantity of liquid photoresist is applied to the substrate either before or during rotation of the substrate; soft bake, in which most of the solvent in the resist is driven off by heating the substrate; alignment and exposure, in which a mask or reticle corresponding to the desired circuit pattern is aligned to the correct location on the substrate and light energy is applied through the mask or reticle onto the photoresist to define circuit patterns which will be etched in a subsequent processing step to define the circuits on the substrate; post-exposure bake; develop, in which the soluble areas of photoresist are dissolved by liquid developer, leaving visible islands and windows corresponding to the circuit pattern on the substrate surface; hard bake, in which the remaining photoresist solvent is evaporated from the substrate; and develop inspect, in which an inspection is carried out in order to verify the quality of the resist pattern.

Resists which are determined by development inspection to be defective can be removed through resist stripping for re-processing of the substrate. Those resists which are determined not to be defective are subjected to etching, in which those areas of a conductive layer on the substrate not covered by the photoresist are etched and those areas covered by the photoresist are protected, leaving the circuit pattern in the conductive layer on the substrate. Alternatively, the photoresist may cover an electrically-insulating dielectric layer, in which case the areas of the dielectric layer not covered by the photoresist are etched and those areas covered by the photoresist are protected, leaving the circuit pattern etched in the form of vias, trenches, or both vias and trenches in the dielectric layer. The vias and/or trenches are then filled with metal in a deposition process to form the circuit pattern.

Since the processing of silicon wafers requires extreme cleanliness in the processing environment to minimize the presence of contaminating particles or films, the surface of the silicon wafer is frequently cleaned after each processing step. For instance, the wafer surface is frequently cleaned after development of the photoresist. A frequently-used method for cleaning the surface of the developed photoresist is a spin-rinse-dry (SRD) cleaning process.

In an SRD cleaning process, a wafer is normally positioned on a wafer platform which is typically rotatably mounted on a wafer stage. The wafer platform rotates the wafer at a predetermined rotational speed, which may be between typically about 200 RPM and about 2,000 RPM. Simultaneously, a water jet of de-ionized water is ejected onto the upper surface of the rotating wafer from a nozzle opening in the nozzle.

As it strikes the surface of the wafer at an angle of typically about 45 □, the water jet is scanned along a top of the wafer surface by a lateral sweeping motion of the water jet nozzle to define a generally curved or arcuate trace which normally traverses the center of the wafer. The surface of the wafer is scanned by the water jet at least once, and preferably, several times. Centrifugal force acting on the water flow on the surface of the wafer due to the rotating wafer platform and wafer removes contaminating particles or films from the surface of the wafer. Horizontal movement of the wafer stage beneath the water jet nozzle during the scrubbing process provides a more uniform dispersement of the sprayed water along the entire surface of the disc. After completion of the jet-scrubbing process, the wafer is subjected to a spin-drying step in which the wafer is rotated and nitrogen or clean dry air (CDA) is blown against the wafer surface.

A typical conventional process flow of an SRD cleaning process after photoresist development is shown in FIG. 1. In step 1, pre-development photolithography processes are carried out on the wafer. These typically include vapor prime, spin coat, soft bake, alignment and exposure, and post-exposure bake. In step 2, the photoresist is developed. In step 3, the developed photoresist is rinsed with deionized water. In step 4, the wet photoresist is spin-dried. In step 5, post-development photolithography steps, including hard bake and develop inspect, are carried out.

One of the limitations of the SRD drying step is that rotation of the wafer frequently results in electrostatic charging of the wafer surface. The presence of electrostatic charges on the surface of the wafer increases particle contamination of the wafer surface. This ultimately leads to defect densities in the finished chips or die fabricated on the wafer, as revealed by chip testing. Furthermore, electrostatic charges on the surface of the wafer frequently interferes with the operation of production equipment, thus decreasing up-time, interrupting process flow or requiring re-processing of the semiconductor products. The problems caused by electrostatic charges tend to be more of a problem in photolithography areas than in other areas of semiconductor production. Accordingly, a method for reducing or eliminating wafer charging during spin-rinse-drying of wafers, particularly after a photolithography development step, is needed.

An object of the present invention is to provide a novel method suitable for reducing electrostatic charging of wafers during spin-rinse-drying of the wafers.

Another object of the present invention is to provide a novel wafer-charging reduction method which reduces the number of defects in a chip or die fabricated on a wafer.

Still another object of the present invention is to provide a novel method which is suitable for reducing electrostatic charging of wafers during wafer spin-drying, which method includes rinsing a wafer; applying an ionic solution to the wafer; and spin-drying the wafer, wherein the ionic solution prevents or reduces accumulation of electrostatic charges on the wafer during the spin-drying step.

Yet another object of the present invention is to provide a novel wafer-charging reduction method, which includes applying an acidic or alkaline ionic solution to a wafer prior to a spin-drying step to prevent or reduce the accumulation of electrostatic charges on the wafer during wafer drying.

### SUMMARY OF THE INVENTION

In accordance with these and other objects and advantages, the present invention is generally directed to a novel method for eliminating or reducing the accumulation of electrostatic charges on semiconductor wafers during spin-rinse-drying of the wafers in the fabrication of integrated circuits (ICs), particularly during photolithography. The method includes rinsing a wafer; applying an ionic solution to the wafer; and spin-drying the wafer. During the spin-drying step, the ionic solution neutralizes electrostatic charges on the wafer as the wafer is rotated. This reduces the formation of defects in devices fabricated on the wafer, as well as prevents or reduces electrostatic interference with processing equipment during photolithographic and other fabrication processes. The ionic solution can be either acidic or alkaline. Preferably, the ionic solution has a pH of typically about 6˜10.

### BRIEF DESCRIPTION OF THE DRAWINGS

The invention will now be described, by way of example, with reference to the accompanying drawings, in which:

FIG. 1 is a flow diagram illustrating a typical sequence of process steps carried out according to a conventional photolithography process, illustrating development and rinsing of photoresist immediately followed by spin-drying of the photoresist;

FIG. 2 is a flow diagram illustrating a typical sequence of process steps carried out in a photolithography process, illustrating development and rinsing of a photoresist, followed by application of an ionic solution to the photoresist prior to the spin-drying step according to the method of the present invention;

FIG. 3A is a schematic view of a spin-rinse-dry (SRD) station, illustrating rinsing of a photoresist on the wafer according to the method of the present invention;

FIG. 3B is a schematic view of an SRD station, illustrating application of an ionic solution to the wafer after the rinsing step of FIG. 3A, followed by spin-drying of the wafer, according to the method of the present invention; and

FIG. 4 is a flow diagram illustrating sequential process steps carried out according to an alternative embodiment of the method of the present invention.

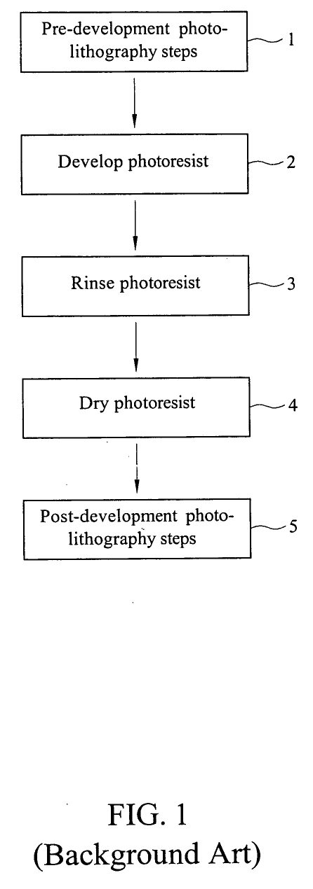

### DETAILED DESCRIPTION OF THE INVENTION

The present invention contemplates a novel method for eliminating or at least reducing the accumulation of electrostatic charges on semiconductor wafers during spin-rinse-drying of the wafers in the fabrication of integrated circuits (ICs), particularly during the photolithography stage of semiconductor fabrication. According to the method, a wafer is initially rinsed typically in a spin-rinse-dry (SRD) module. An ionic solution is then applied to the wafer, which is then subjected to a spin-drying step. During the spin-drying step, the ionic solution neutralizes electrostatic charges on the rotating wafer. Consequently, electrostatic attraction of particles to the wafer is reduced. This, in turn, reduces the formation of defects in devices fabricated on the wafer. Furthermore, electrostatic interference with processing equipment during photolithographic and other fabrication processes is eliminated or at least substantially reduced.

The ionic solution applied to the wafer according to the method of the present invention can be either acidic or alkaline. Examples of acidic ionic solutions which are suitable for implementation of the present invention include aqueous solutions of carbonic acid (H₂CO₃), sulfuric acid (H₂SO₄) and hydrochloric acid (HCl), in non-exclusive particular. Examples of alkaline ionic solutions which are suitable for implementation of the present invention include aqueous solutions of sodium hydroxide (NaOH) and potassium hydroxide (KOH), in non-exclusive particular. Preferably, the ionic solution has a pH of typically about 6˜10. The acidic or alkaline species has a predetermined concentration in the aqueous ionic solution.

The method of the present invention is typically implemented during a photolithography process to prevent the accumulation of electrostatic charges on wafers during a spin-dry step of wafer cleaning. The method of the present invention is particularly suited for preventing the accumulation of electrostatic charges on a wafer during a spin-rinse-drying step, which is carried out after development of photoresist on a wafer during photolithography. However, it is understood that the present invention is equally adaptable to preventing the accumulation of electrostatic charges on wafers during a spin-rinse-dry step in areas of semiconductor processing not limited to photolithography.

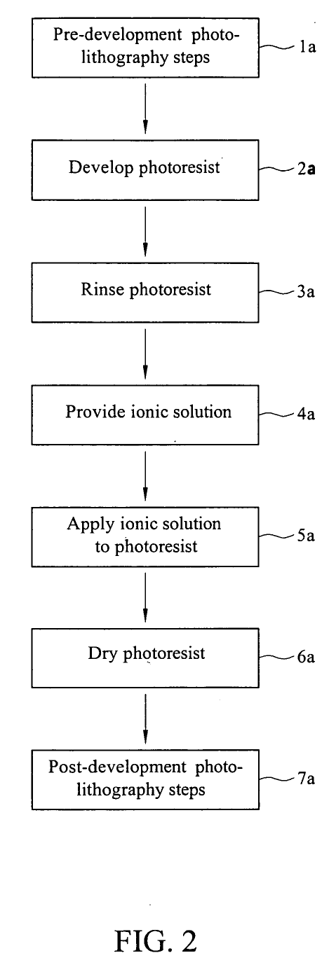

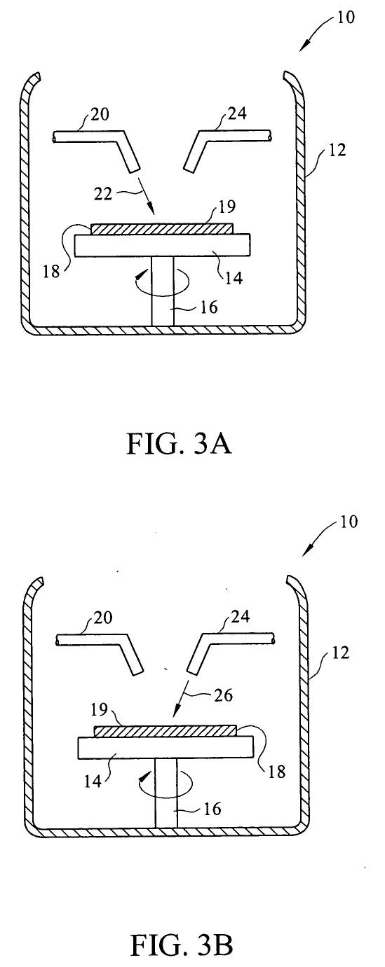

Referring to the flow diagram of FIG. 2, in conjunction with the schematic views of FIGS. 3A and 3B, in typical implementation of the method of the present invention, a wafer 18 (FIGS. 3A and 3B) is subjected to photolithography steps during the fabrication of integrated circuit devices (not shown) on the wafer 18. The photolithography process is typically preceded by deposition of a metal or dielectric layer (not shown) on the wafer 18, using process equipment and parameters which are well-known by those skilled in the art. Photolithography is then carried out to pattern and etch trenches, vias and/or other openings in the metal or dielectric layer to form circuit patterns that will ultimately define the integrated circuit devices. Alternatively, the photolithography process may be carried out to pattern and etch openings in the surface of the wafer 18.

After deposition of the metal or dielectric layer (not shown) on the wafer 18, a series of pre-development photolithography steps is carried out on the wafer 18, as indicated in step 1a of FIG. 2. These steps may be conventional and typically include a vapor prime step, a spin coat step, a soft bake step, an alignment and exposure step and a post-exposure bake (PEB) step. At the vapor prime step, the surface of the metal or dielectric layer on the wafer 18, or the surface of the wafer 18, is cleaned, dehydrated and primed with an adhesion promoter such as hexamethyldisilazane (HMDS) to promote adhesion between the photoresist and the layer or wafer surface.

At the spin coat step, the layer or wafer surface is coated with a photoresist material using a spin-coating method to form a photoresist layer 19. At the soft bake step, the photoresist 19 is subjected to soft bake temperatures of typically about 90˜100 degrees C. for typically about 30 seconds on a hot plate to drive off most of the solvent in the photoresist 19. The soft bake step improves adhesion, promotes uniformity of the photoresist 19 on the wafer 18, and facilitates precise linewidth control during etching. After soft baking, the wafer 18 is typically subjected to a cooling step on a cool plate to achieve uniform photoresist characteristics.

At the alignment and exposure step, a mask or reticle is aligned with multiple exposure fields on the photoresist 19. At each exposure field alignment, UV light is transmitted through the mask or reticle to transfer a circuit pattern from the mask or reticle onto the photoresist 19. The UV light activates photosensitive components in the photoresist 19, causing chemical changes in the form of the circuit pattern features. At the post-exposure bake (PEB) step, the wafer 18 is heated on a hot plate to temperatures of typically about 100˜110 degrees C. This step is particularly necessary for deep UV (DUV) resists and is carried out immediately after the alignment and exposure step.

After the pre-development photolithography steps have been carried out on the wafer 18, the photoresist 19 is developed, as indicated in step 2a of FIG. 2. The photoresist development step is the critical step for creating the circuit pattern in the photoresist 19. During development, the soluble areas of the photoresist 19 are dissolved using liquid developer chemicals. This step leaves in the photoresist 19 patterns of islands and windows, which correspond to the trenches, vias and other openings that together define the pattern of the circuit devices to be formed on the wafer 18.

After development of the photoresist 19 on the wafer 18 is completed, the wafer 18 is subjected to a rinsing step, as indicated in step 3a, to remove photoresist particles from the wafer 18. This may be carried out in an SRD (spin-rinse-dry) station 10, which may be conventional and is shown in FIG. 3A. The SRD station 10 typically includes a cup-shaped chamber 12 within which is provided a wafer support 14 on a shaft 16. The wafer 18 is supported on the wafer support 14, and dispensing arms 20, 24 are positional over the wafer 18.

During the photoresist-rinsing step 3a, a jet of pressurized deionized (DI) water 22 is ejected from the dispensing arm 20 and onto the photoresist 19 on the wafer 18. Simultaneously, the wafer support 14 rotates the wafer 18 at a predetermined rotational speed, which may be between typically about 200 RPM and about 2,000 RPM. The DI water 22 typically strikes the center of the wafer 18 and is drawn outwardly by centrifugal force toward the edge of the wafer 18, washing residual photoresist particles from the photoresist layer 19.

According to the method of the present invention, after the photoresist-rinsing step 3a, an ionic solution 26 (FIG. 3B) is provided. The ionic solution 26 may be an acidic aqueous solution, such as aqueous carbonic acid (H₂CO₃), sulfuric acid (H₂SO₄) or hydrochloric acid (HCl), in non-exclusive particular. Alternatively, the ionic solution 26 may be an alkaline aqueous solution, such as aqueous sodium hydroxide (NaOH) or potassium hydroxide (KOH), in non-exclusive particular. Preferably, the ionic solution 26 has a pH of typically about 6˜10.

As indicated in step 5a, the ionic solution 26 is next applied to the photoresist 19 on the wafer 18. As shown in FIG. 3B, this step may be carried out in the SRD station 10, by dispensing the ionic solution 26 from the dispensing arm 24 onto the photoresist 19 as the wafer support 14 rotates the wafer 18 at a rotational speed of between typically about 200 RPM and about 2,000 RPM. The ionic solution 26 is typically dispensed onto the photoresist 19 at the center of the wafer 18, such that the ionic solution 26 is drawn from the center to the edges of the wafer 18, over the surface of the photoresist 19. Preferably, the ionic solution 26 is dispensed onto the photoresist 19 until the ionic solution 26 substantially covers the entire surface of the photoresist 19, at which time dispensing of the ionic solution 26 onto the photoresist 19 is stopped.

As indicated in step 6a, the photoresist 19 is then dried by continuing to rotate the wafer 18 until the ionic solution 26 is dried from the photoresist 19. As the wafer 18 is rotated, the ionic solution 26 remaining on the photoresist 19 neutralizes electrostatic charges on the photoresist 19. This charge-neutralizing action therefore prevents or minimizes accumulation of electrostatic charges on the wafer 18 which would otherwise tend to attract particles to the wafer 18, induce defects in the devices formed on the wafer 18 and interfere with proper operation of processing equipment used in the ensuing post-development photolithography and other semiconductor fabrication steps.

As indicated in step 7a, following the drying step 6a, the photoresist 19 on the wafer 18 is subjected to post-development photolithography steps to complete the photolithography process. These steps typically include a hard bake step, followed by a develop inspect step. At the hard bake step, the wafer 18 is heated to temperatures of typically about 120˜140 degrees C. to evaporate the remaining photoresist solvent from the photoresist 19 and improve adhesion of the photoresist 19 to the surface of the wafer 18. At the develop inspect step, the photoresist 19 is inspected in order to identify wafers having defective photoresists and to characterize the performance of the photoresist process for improvement purposes.

Referring next to FIG. 4, a flow diagram illustrating sequential process steps carried out according to an alternative embodiment of the method of the present invention is shown. In step 1, a wafer is coated with a photoresist. In step 2, the photoresist is exposed through a mask to define a circuit pattern on the photoresist. In step 3, the photoresist is developed by transferring the wafer into a developing chamber and applying a developing solution to the wafer in the developing chamber. In step 4, carbon dioxide gas is dissolved in deionized (DI) water. This step is typically carried out prior to transfer of the wafer into the developing chamber and may involve injection of the carbon dioxide into a tank containing the deionized water. The developed photoresist is then rinsed with the deionized water with dissolved carbon dioxide (step 5), after which the wafer is spin-dried (FIG. 6).

Application of the deionized water with dissolved carbon dioxide to the photoresist after photoresist development, in the manner heretofore described, eliminates or reduces static charging of the wafer surface during spin-drying. Consequently, the stability and reliability of devices fabricated on the wafer are improved, and CD SEM (scanning electron micrograph) performance is enhanced. Furthermore, the process can be implemented without adversely affecting wafer throughput and without wafer damage or contamination.

While the preferred embodiments of the invention have been described above, it will be recognized and understood that various modifications can be made in the invention and the appended claims are intended to cover all such modifications which may fall within the spirit and scope of the invention.

What is claimed is:

1. A method for reducing wafer charging during drying, comprising:
providing a wafer;
rinsing said wafer;
providing an ionic solution;
applying said ionic solution to said wafer; and
spin-drying said wafer.

2. The method of claim 1 wherein said ionic solution is an acidic ionic solution.

3. The method of claim 1 wherein said rinsing said wafer comprises rotating said wafer and dispensing water on said wafer.

4. The method of claim 3 wherein said ionic solution is an acidic ionic solution.

5. The method 1 wherein said ionic solution is an alkaline ionic solution.

6. The method of claim 5 wherein said rinsing said wafer comprises rotating said wafer and dispensing water on said wafer.

7. The method of claim 2 wherein said ionic solution has a pH of about 6.

8. The method of claim 7 wherein said rinsing said wafer comprises rotating said wafer and dispensing water on said wafer.

9. The method of claim 5 wherein said ionic solution has a pH of about 8.

10. The method of claim 9 wherein said rinsing said wafer comprises rotating said wafer and dispensing water on said wafer.

11. A method for reducing wafer charging during drying, comprising:
providing a wafer;
providing a photoresist layer on said wafer;
developing said photoresist layer;
rinsing said photoresist layer;
providing an ionic solution;
applying said ionic solution to said photoresist layer; and
spin-drying said photoresist layer.

12. The method of claim 11 wherein said ionic solution is an acidic ionic solution selected from the group consisting of a carbonic acid ionic solution, a sulfuric acid ionic solution and a hydrochloric acid ionic solution.

13. The method of claim 12 wherein said ionic solution has a pH of about 6.

14. The method of claim 11 wherein said rinsing said photoresist layer comprises rotating said wafer and dispensing water on said photoresist layer.

15. The method of claim 11 wherein said ionic solution is an alkaline ionic solution selected from the group consisting of a sodium hydroxide ionic solution and a potassium hydroxide ionic solution.

16. The method of claim 15 wherein said ionic solution has a pH of about 8.

17. A method for reducing wafer charging during drying, comprising:
providing a wafer;
providing a photoresist layer on said wafer;
developing said photoresist layer;
rinsing said photoresist layer;
providing an ionic solution having a pH of from about 6 to about 8;
applying said ionic solution to said photoresist layer; and
spin-drying said photoresist layer.

18. The method of claim 17 wherein said ionic solution is an acidic ionic solution having a pH of about 6 and selected from the group consisting of a carbonic acid ionic solution, a sulfuric acid ionic solution and a hydrochloric acid ionic solution.

19. The method of claim 17 wherein said ionic solution is an alkaline ionic solution having a pH of about 8 and selected from the group consisting of a sodium hydroxide ionic solution and a potassium hydroxide ionic solution.

20. The method of claim 17 wherein said rinsing said photoresist layer comprises rotating said wafer and dispensing water on said photoresist layer.

21. A method for developing an exposed wafer, comprising:
providing a wafer;
coating said wafer with photoresist;
providing a mask and exposing said photoresist through said mask;
developing said photoresist;
forming a carbon dioxide/water mixture by dissolving carbon dioxide in deionized water;
applying said carbon dioxide/water mixture to said photoresist; and
spin-drying said wafer.
